(19) United States
(12) Patent Application Publication
(10) Pub. No.: US 2019/0305124 A1
(43) Pub. Date: Oct. 3, 2019

(54) SEMICONDUCTOR DEVICE AND MANUFACTURING METHOD FOR SEMICONDUCTOR DEVICE

(71) Applicant: TOYOTA JIDOSHA KABUSHIKI KAISHA, Toyota-shi (JP)

(72) Inventors: Atsushi WATANABE, Toyota-shi (JP); Hiroyuki UEDA, Nagakute-shi (JP); Tomohiko MORI, Nagakute-shi (JP)

(73) Assignee: TOYOTA JIDOSHA KABUSHIKI KAISHA, Toyota-shi (JP)

(21) Appl. No.: 16/298,068

(22) Filed: Mar. 11, 2019

(30) Foreign Application Priority Data
Mar. 27, 2018 (JP) 2018-059700

(51) Int. Cl. H01L 29/78; H01L 29/20; H01L 29/10; H01L 29/08; H01L 29/66

(52) U.S. Cl. CPC H01L 29/7802; H01L 29/2003; H01L 29/66712; H01L 29/0865; H01L 29/1095

(57) ABSTRACT

A semiconductor device includes an n-type first drift layer, an i-type or an n-type withstand voltage layer disposed on top of the first drift layer, a p-type body layer disposed on top of the withstand voltage layer, an n-type second drift layer that is disposed on top of the first drift layer, is in contact with side surfaces of the withstand voltage layer and the body layer, an n-type source layer that is disposed on top of the body layer, is separated from the first drift layer, the second drift layer, and the withstand voltage layer by the body layer, and a gate electrode that faces the body layer through a gate insulating film, the body layer being positioned between the second drift layer and the source layer. The withstand voltage layer is made from a material having a bandgap larger than that of the first drift layer.

### INCORPORATION BY REFERENCE

The disclosure of Japanese Patent Application No. 2018-059700 filed on Mar. 27, 2018 including the specification, drawings and abstract is incorporated herein by reference in its entirety.

### BACKGROUND

### 1. Technical Field

The disclosure relates to a semiconductor device and a method for a semiconductor device.

### 2. Description of Related Art

“Development of SiO₂/GaN MOSFETs on a homo-epitaxial GaN layer” by Katsunori UENO in OYO-BUTSURI, Vol. 86, No. 05, pp. 376-380 (2017) discloses a MOS-type semiconductor device. This semiconductor device includes a first drift layer (an n⁻-GaN layer), a body layer (a p-well), a second drift layer (a JFET portion), a source layer, and a gate electrode. The body layer is disposed on top of the first drift layer. The second drift layer is disposed on top of the first drift layer and is in contact with a side surface of the body layer. The source layer is disposed on top of the body layer and is separated from the first drift layer and the second drift layer by the body layer. The gate electrode faces the body layer through a gate insulating film, the body layer being positioned between the source layer and the second drift layer. When a given potential is applied to the gate electrode, a channel is formed in the body layer, and the source layer and the second drift layer are connected with each other. As a result, current flows between the source layer and the first drift layer.

### SUMMARY

When a semiconductor device described in “Development of SiO₂/GaN MOSFETs on a homo-epitaxial GaN layer” by Katsunori UENO in OYO-BUTSURI, Vol. 86, No. 05, pp. 376-380 (2017) is turned off, a depletion layer spreads from an interface between a body layer and a first drift layer towards its surrounding area. Therefore, a high electric field tends to be generated in the first drift layer near the interface. When an excessively high electric field is generated in the first drift layer, withstand voltage of the semiconductor device may be affected. Therefore, in the specification, a semiconductor device with high withstand voltage is proposed.

A semiconductor device according to a first aspect disclosed in the specification includes a first drift layer, a withstand voltage layer, a body layer, a second drift layer, a source layer, and a gate electrode. The first drift layer contains an n-type impurity. The withstand voltage layer is disposed on top of the first drift layer and contains an i-type or the n-type impurity. The body layer is disposed on top of the withstand voltage layer and contains a p-type impurity. The second drift layer is disposed on top of the first drift layer, is in contact with a side surface of the withstand voltage layer and a side surface of the body layer, and contains the n-type impurity. The source layer is disposed on top of the body layer, is separated from the first drift layer, the second drift layer and the withstand voltage layer by the body layer, and contains the n-type impurity. The gate electrode faces the body layer through a gate insulating film, the body layer being positioned between the second drift layer and the source layer. The withstand voltage layer is made from a material having a bandgap larger than that of the first drift layer.

The withstand voltage layer may be disposed beneath the entire body layer or beneath a part of the body layer.

In the above aspect, the withstand voltage layer may be in contact with an end portion of a lower surface of the body layer on a side of the second drift layer.

In the above aspect, the first drift layer may be made from GaN, and the withstand voltage layer may be made from AlGaN or AN.

In the above aspect, a concentration of the n-type impurity in the withstand voltage layer may be lower than a concentration of the n-type impurity in the first drift layer.

In the above aspect, a concentration of the n-type impurity in the second drift layer may be lower than the concentration of the n-type impurity in the first drift layer.

In the above aspect, the body layer may include a first body layer and a second body layer. The first body layer is disposed on top of the withstand voltage layer, and the second body layer contains the p-type impurity less concentrated than that of the first body layer, is disposed on top of the first body layer, and faces the gate electrode between the second drift layer and the source layer.

The semiconductor device according to the above aspect may further include a drain layer. The drain layer is in contact with a bottom of the first drift layer and contains the n-type impurity more concentrated than that of the first drift layer.

A manufacturing method for a semiconductor device according to a second aspect disclosed in the specification includes allowing a withstand voltage layer to grow on top of a first drift layer, the withstand voltage layer being made from AlGaN and containing an i-type or an n-type impurity, the first drift layer being made from GaN and containing the n-type impurity, forming a body layer on top of the withstand voltage layer, the body layer containing a p-type impurity, forming an opening by etching, the opening penetrating the body layer and the withstand voltage layer and reaching the first drift layer, forming a second drift layer inside the opening, the second drift layer containing the n-type impurity, forming a source layer that contains the n-type impurity and is separated from the first drift layer, the second drift layer, and the withstand voltage layer by the body layer, and forming a gate electrode that faces the body layer through a gate insulating film, the body layer being positioned between the source layer and the second drift layer.

In the semiconductor device according to the aspect of the disclosure, the withstand voltage layer is disposed in at least a part of a range of an interface between the first drift layer and the body layer. This means that, in the range, the withstand voltage layer is disposed on top of the first drift layer, and the body layer is disposed on top of the withstand voltage layer. Therefore, when the semiconductor device is turned off, a depletion layer spreads from an interface between the body layer and the withstand voltage layer. Therefore, a high electric field is generated inside the withstand voltage layer in the vicinity of the interface. Since the withstand voltage layer is made from a material having a large bandgap, even if a high electric field is applied, dielectric breakdown hardly happens. Also, since the first drift layer underneath the withstand voltage layer is far from the body layer, a very high electric field is not generated in the first drift layer underneath the withstand voltage layer. Therefore, dielectric breakdown hardly happens in the first drift layer underneath the withstand voltage layer. Therefore, the semiconductor device has high withstand voltage.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a sectional view of a semiconductor device 10;

FIG. 2 is a view describing a manufacturing step for the semiconductor device 10;

FIG. 3 is a view describing a manufacturing step for the semiconductor device 10;

FIG. 4 is a view describing a manufacturing step for the semiconductor device 10;

FIG. 5 is a view describing a manufacturing step for the semiconductor device 10;

FIG. 6 is a view describing a manufacturing step for the semiconductor device 10;

FIG. 7 is a view describing a manufacturing step for the semiconductor device 10;

FIG. 8 is a view describing a manufacturing step for the semiconductor device 10;

FIG. 9 is a view describing a manufacturing step for the semiconductor device 10; and

FIG. 10 is a sectional view of a semiconductor device according to a modification.

### DETAILED DESCRIPTION OF EMBODIMENTS

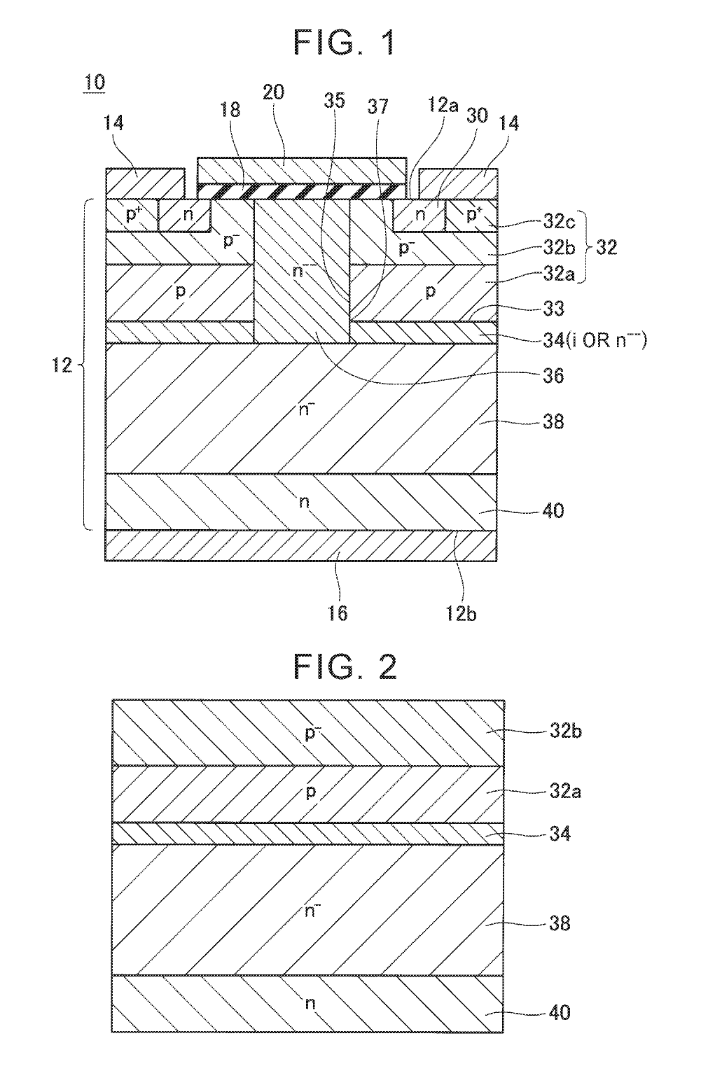

A semiconductor device 10 according to an embodiment shown in FIG. 1 includes a semiconductor substrate 12, a source electrode 14, a drain electrode 16, a gate insulating film 18, and a gate electrode 20. The source electrode 14, the gate insulating film 18, and the gate electrode 20 are disposed on top of an upper surface 12a of the semiconductor substrate 12. The source electrode 14 is in contact with a part of the upper surface 12a. The gate insulating film 18 is in contact with the upper surface 12a in a range where the source electrode 14 is not provided. The gate electrode 20 is disposed on top of the gate insulating film 18. The gate electrode 20 is insulated from the semiconductor substrate 12 by the gate insulating film 18. The gate electrode 20 faces a semiconductor layer located underneath the gate insulating film 18 through the gate insulating film 18. The drain electrode 16 is in contact with the entire region of a lower surface 12b of the semiconductor substrate 12

The semiconductor substrate 12 includes a drain layer 40, a first drift layer 38, a withstand voltage layer 34, a body layer 32, a second drift layer 36, and a source layer 30.

The drain layer 40 is an n-type layer and has a high n-type impurity concentration. The drain layer 40 is made from gallium nitride (GaN). The drain layer 40 is disposed in a range including the entire region of the lower surface 12b. The drain layer 40 is in ohmic contact with the drain electrode 16.

The first drift layer 38 is an n-type layer and has an n-type impurity concentration lower than that of the drain layer 40. The first drift layer 38 is made from GaN. The first drift layer 38 is disposed on top of the drain layer 40 and in contact with an upper surface of the drain layer 40.

The withstand voltage layer 34 is an n-type or an i-type layer and has an n-type impurity concentration lower than that of the first drift layer 38. The withstand voltage layer 34 is made from aluminum gallium nitride (AlGaN). Therefore, a bandgap of the withstand voltage layer 34 (that is AlGaN) is larger than a bandgap of the first drift layer 38 (that is GaN). The withstand voltage layer 34 is disposed on top of the first drift layer 38 and in contact with an upper surface of the first drift layer 38. A thickness of the withstand voltage layer 34 is smaller than that of the first drift layer 38.

The body layer 32 is a p-type layer. The body layer 32 includes a first body layer 32a, a second body layer 32b, and a third body layer 32c.

The first body layer 32a has a relatively high p-type impurity concentration. The first body layer 32a is made from GaN. The first body layer 32a is disposed on top of the withstand voltage layer 34 and in contact with an upper surface of the withstand voltage layer 34.

The second body layer 32b has a p-type impurity concentration lower than that of the first body layer 32a. The second body layer 32b is made from GaN. The second body layer 32b is disposed on top of the first body layer 32a and in contact with an upper surface of the first body layer 32a. The second body layer 32b is disposed in a range that includes a part of the upper surface 12a of the semiconductor substrate 12. The second body layer 32b is in contact with the gate insulating film 18 on the upper surface 12a.

The third body layer 32c has a p-type impurity concentration higher than that of the first body layer 32a. The third body layer 32c is made from GaN. The third body layer 32c is disposed on top of the second body layer 32b and is in contact with the second body layer 32b. The third body layer 32c is disposed in a range that includes a part of the upper surface 12a of the semiconductor substrate 12. The third body layer 32c is in ohmic contact with the source electrode 14 on the upper surface 12a.

The source layer 30 is an n-type layer and has a high n-type impurity concentration. The source layer 30 is made from GaN. The source layer 30 is disposed on top of the second body layer 32b and in contact with the second body layer 32b. The source layer 30 is disposed in a range that includes a part of the upper surface 12a of the semiconductor substrate 12. On the upper surface 12a, the source layer 30 is disposed between the second body layer 32b and the third body layer 32c. The source layer 30 is in ohmic contact with the source electrode 14 at a position adjacent to the third body layer 32c. Also, the source layer 30 is in contact with the gate insulating film 18 at a position adjacent to the second body layer 32b.

There are a partial region on top of the first drift layer 38 where the withstand voltage layer 34 and the body layer 32 are not provided. In that region, the second drift layer 36 is disposed. The second drift layer 36 is an n-type layer and has an n-type impurity concentration lower than the first drift layer 38. The second drift layer 36 is made from GaN. The second drift layer 36 is in contact with the upper surface of the first drift layer 38. The second drift layer 36 extends from the upper surface 12a of the semiconductor substrate 12 down to the first drift layer 38. The second drift layer 36 is in contact with side surfaces of the second body layer 32b, the first body layer 32a, and the withstand voltage layer 34. On the upper surface 12a, the second drift layer 36 is disposed at a position adjacent to the second body layer 32b. In other words, on the upper surface 12a, the second body layer 32b is disposed between the second drift layer 36 and the source layer 30. The second drift layer 36 is in contact with the gate insulating film 18 at a position adjacent to the second body layer 32b.

The source layer 30 is separated from the first drift layer 38, the second drift layer 36, and the withstand voltage layer 34 by the body layer 32. The gate insulating film 18 covers a range across the source layer 30, the second body layer 32b, and the second drift layer 36 on the upper surface 12a. The gate electrode 20 covers an entire upper surface of the gate insulating film 18. Therefore, the gate electrode 20 faces the source layer 30, the second body layer 32b, and the second drift layer 36 through the gate insulating film 18.

The semiconductor device 10 configures a metal oxide semiconductor field effect transistor (MOSFET). When a potential of a threshold value or higher is applied to the gate electrode 20, a channel is formed in the second body layer 32b near the gate insulating film 18. The source layer 30 and the second drift layer 36 are connected with each other by the channel. In a state where the channel is formed, when a potential higher than that of the source electrode 14 is applied to the drain electrode 16, electrons flow from the source electrode 14 to the drain electrode 16 through the source layer 30, the channel, the second drift layer 36, the first drift layer 38, and the drain layer 40. This means that the MOSFET is turned on. In the semiconductor device 10 according to the embodiment, since the n-type impurity concentration of the first drift layer 38 is higher than the n-type impurity concentration of the second drift layer 36, resistance of the first drift layer 38 is low. Therefore, the electrons are able to pass through the first drift layer 38 with a low loss. Thus, by setting the n-type impurity concentration of the first drift layer 38 so as to be higher than the n-type impurity concentration of the second drift layer 36, it is possible to reduce on-resistance of the MOSFET.

When a potential applied to the gate electrode 20 is reduced so as to be lower than the threshold value, the channel disappears, and the flow of the electrons stops. This means that the MOSFET is turned off. Once the MOSFET is turned off, a depletion layer spreads from an interface 35 between the body layer 32 and the second drift layer 36 (an interface between the p-type and the n-type layers), and an interface 33 between the body layer 32 and the withstand voltage layer 34 (an interface between the p-type and the n-type layers, or an interface between the p-type and an i-type layers) towards their peripheries.

In the second drift layer 36, the depletion layer spreads from the interface 35. In the embodiment, because the n-type impurity concentration of the second drift layer 36 is lower than the n-type impurity concentration of the first drift layer 38, the depletion layer easily spreads in the second drift layer 36. Therefore, the second drift layer 36 is depleted almost entirely. Hence, application of a high electric field to the gate insulating film 18 is restrained.

Since the p-type impurity concentration of the first body layer 32a is high, the depletion layer extending from the interface 33 scarcely extends to the first body layer 32a side (an upper side). Thus, the depletion layer extending from the interface 33 is prevented from reaching the source layer 30 (meaning that a punchthrough is prevented).

The depletion layer extending from the interface 33 extends to the withstand voltage layer 34 side (a lower side). The depletion layer extending from the interface 33 extends through the withstand voltage layer 34 and reaches an inside of the first drift layer 38. Thus, the withstand voltage layer 34 and the first drift layer 38 are depleted almost entirely. Therefore, an electric field distribution happens inside the withstand voltage layer 34 and the first drift layer 38.

Inside the depletion layer near the interface 33, a high electric field tends to be generated. In particular, a high electric field tends to be generated underneath a corner portion 37 that is a boundary between the interfaces 33, 35. However, in the embodiment, the withstand voltage layer 34 is provided underneath the entire interface 33 including the underneath of the corner portion 37. Because the n-type impurity concentration of the withstand voltage layer 34 is low, an electric field inside the withstand voltage layer 34 is relaxed. Further, since the withstand voltage layer 34 is made from a material with a large bandgap, dielectric breakdown hardly happens in the withstand voltage layer 34. Therefore, even when a high electric field happens inside the withstand voltage layer 34, dielectric breakdown hardly happens. Thus, the withstand voltage layer 34 restrains dielectric breakdown from happening near the interface 33. Therefore, the semiconductor device 10 has a high withstand voltage.

Further, as described earlier, the depletion layer also spreads in the first drift layer 38. The first drift layer 38 has the n-type impurity concentration higher than those of the withstand voltage layer 34 and the second drift layer 36. Therefore, an effect of electric field relaxation by the n-type impurity concentration is low inside the first drift layer 38. However, since the first drift layer 38 is disposed at a position away from the interface 33, an electric field generated in the first drift layer 38 does not become so high. Therefore, no particular problem happens even when the n-type impurity concentration of the first drift layer 38 is high.

As described earlier, in the semiconductor device 10, because the withstand voltage layer 34 with a large bandgap is disposed below the body layer 32, high withstand voltage in the MOSFET is realized. Further, since the n-type impurity concentration of the first drift layer 38 that is positioned below the withstand voltage layer 34 (that is a range where a high electric field is not generated) is set to be higher than the n-type impurity concentration of the second drift layer 36, low on-resistance in the MOSFET is realized. Thus, with the semiconductor device 10 according to the embodiment, it is possible to realize the MOSFET with high withstand voltage and low on-resistance.

Next, a manufacturing method for the semiconductor device 10 is described. First of all, as shown in FIG. 2, a laminate structure of the drain layer 40, the first drift layer 38, the withstand voltage layer 34, the first body layer 32a, and the second body layer 32b is formed. This means that the first drift layer 38, the withstand voltage layer 34, the first body layer 32a, and the second body layer 32b are epitaxially grown on top of the drain layer 40 in this order. A thickness of the drain layer 40 is about 400 μm, and the n-type impurity concentration of the drain layer 40 is about 1×10¹⁸ cm⁻³. A thickness of the first drift layer 38 is about 5 μm, and the n-type impurity concentration of the first drift layer 38 is about 2×10¹⁶ cm⁻³. A thickness of the withstand voltage layer is about 0.02 μm. A thickness of the first body layer 32a is about 0.5 μm, and the p-type impurity concentration of the first body layer 32a is about 5×10¹⁹ cm⁻³. A thickness of the second body layer 32b is about 1.5 μm, and the p-type impurity concentration of the second body layer 32b is about 5×10¹⁸ cm⁻³. Once each of the layers is formed as shown in FIG. 2, annealing (at 850° C. for five minutes) is carried out in order to activate the p-type impurity.

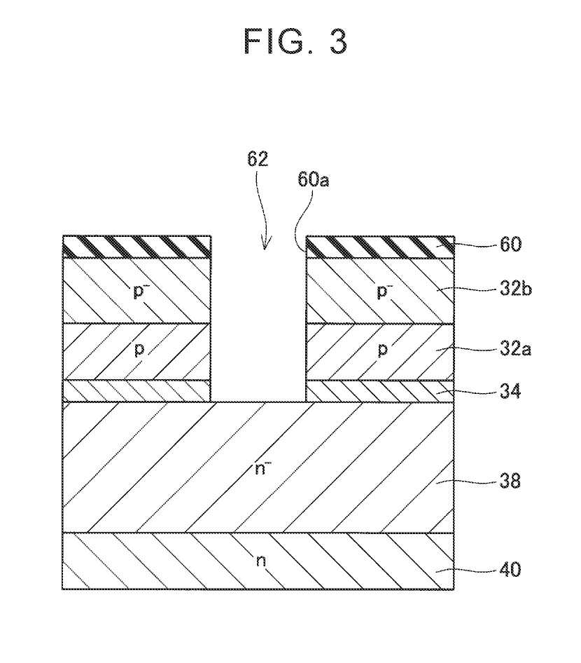

Next, as shown in FIG. 3, a mask 60 (a silicon oxide layer) is formed on top of the second body layer 32b, and the mask 60 is selectively etched by using buffered hydrofluoric acid, thereby forming an opening portion 60a. Next, dry etching of a semiconductor layer inside the opening portion 60a is performed. Thus, an opening 62 is formed that penetrates the second body layer 32b, the first body layer 32a, and the withstand voltage layer 34 and reaches the first drift layer 38. As described earlier, the second body layer 32b and the first body layer 32a are made from GaN, the withstand voltage layer 34 is made from AlGaN, and the first drift layer 38 is made from GaN. Therefore, during the etching step for forming the opening 62, an etching rate changes. More specifically, when the opening 62 reaches the withstand voltage layer 34, an object to be etched changes from GaN to AlGaN, and the etching rate thus drops. Also, when the opening 62 penetrates the withstand voltage layer 34 and reaches the first drift layer 38, an object to be etched is changed from AlGaN to GaN, and the etching rate thus increases. Therefore, by detecting changes in the etching rate, it is possible to determine that the opening 62 has reached the first drift layer 38. Alternatively, when an etching apparatus has a function of detecting an Al ratio, it is possible to determine that the opening 62 has reached the first drift layer 38 when Al is detected once and then no longer detected thereafter. By stopping the etching almost at the same time that the opening 62 reaches the first drift layer 38, a bottom surface of the opening 62 is almost leveled with a surface of the first drift layer 38. Thus, it is possible to prevent excessive etching of the first drift layer 38. After the etching, the mask 60 is removed.

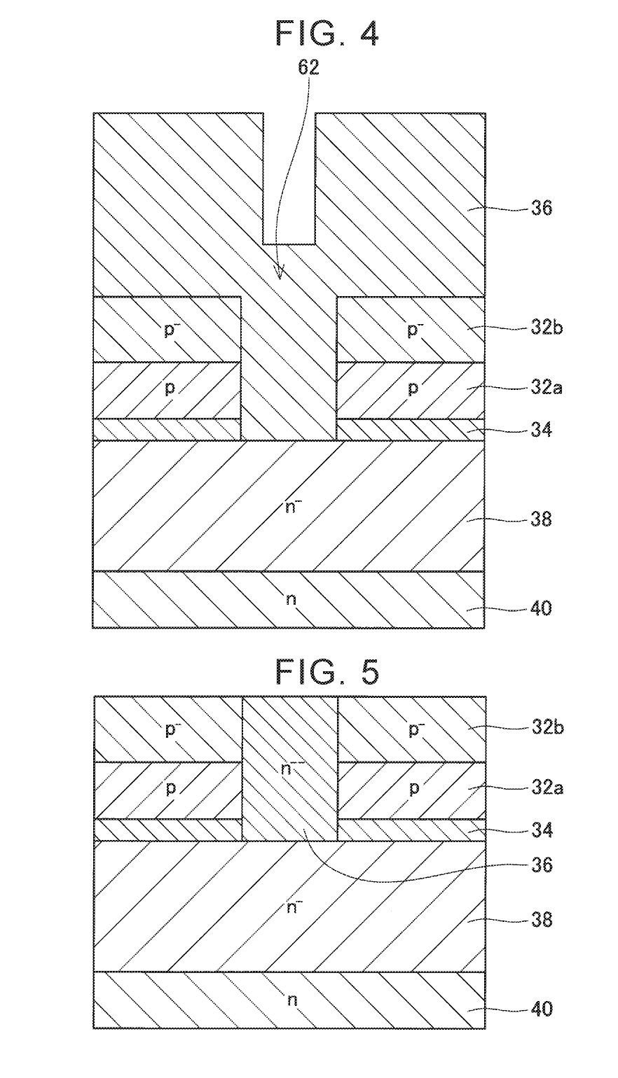

Next, as shown in FIG. 4, the second drift layer 36 is formed by epitaxial growth on the substrate. At this time, the second drift layer 36 is formed inside the opening 62.

Next, as shown in FIG. 5, a surface of the substrate is flattened by chemical mechanical polishing (CMP). Thus, the second drift layer 36 positioned on top of the second body layer 32b is removed. A thickness of the second body layer 32b is smaller than 1.5 μm.

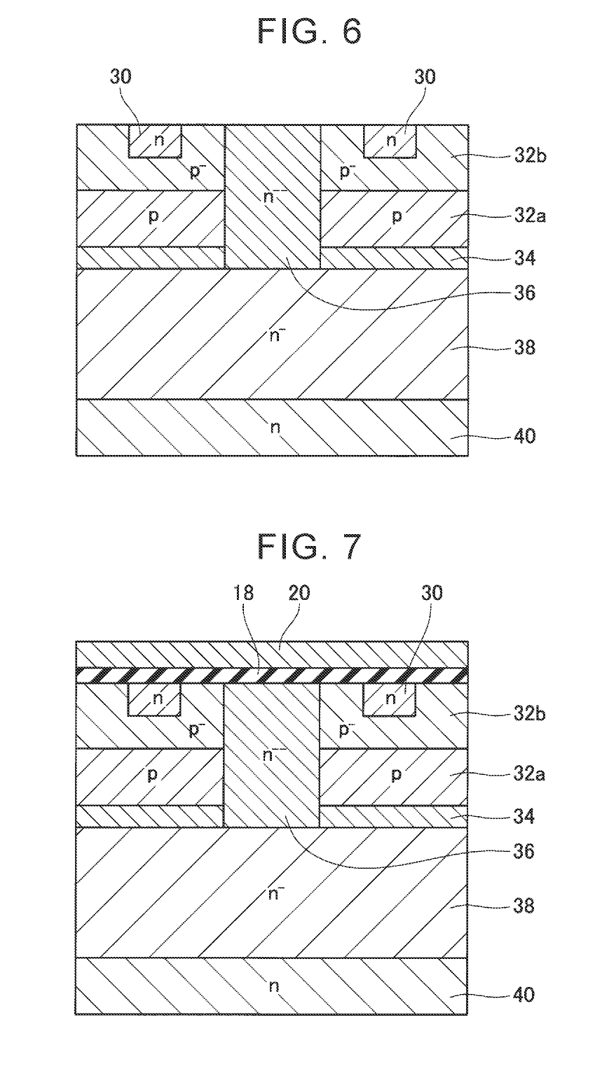

Next, as shown in FIG. 6, the source layer 30 is formed by ion implantation. To be more specific, ion is implanted with a dosage of 3×10¹⁵ cm ⁻², and then the substrate is annealed (at 1000° C. for 20 minutes) in order to activate the implanted n-type impurity. Thus, the source layer 30 is formed.

Next, as shown in FIG. 7, the gate insulating film 18 is formed so as to cover the entire surface of the substrate, and post annealing of the gate insulating film 18 is carried out. Also, the gate electrode 20 is formed on top of the gate insulating film 18.

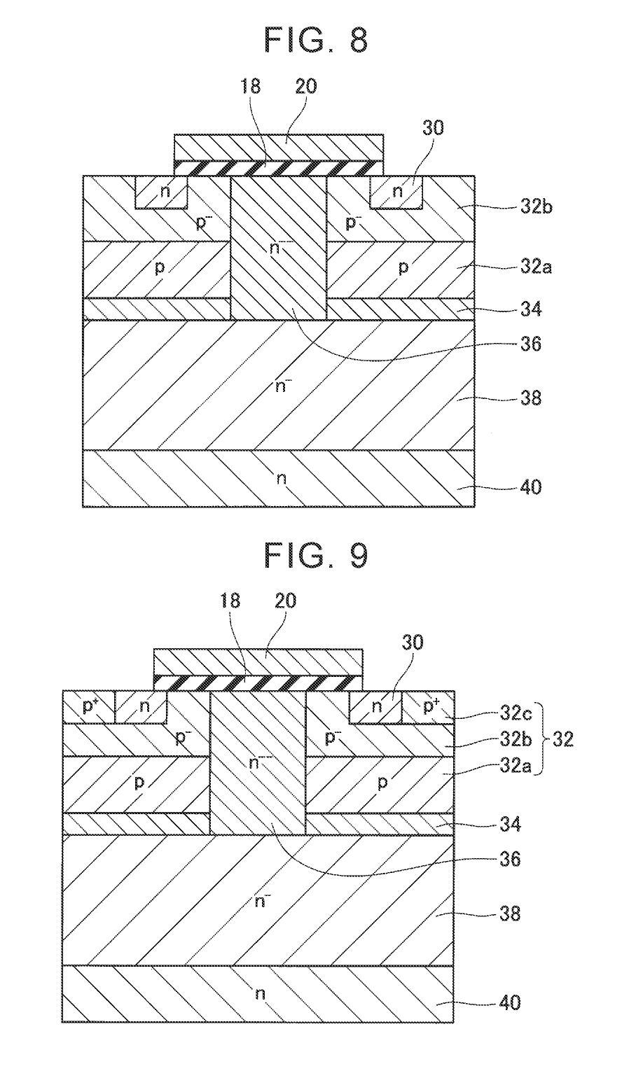

Next, as shown in FIG. 8, the gate insulating film 18 and the gate electrode 20 are patterned.

Next, as shown in FIG. 9, the third body layer 32c is formed by ion implantation.

Next, the source electrode 14 is formed on top of the upper surface of the substrate. Next, the drain electrode 16 is formed on a lower surface of the substrate. With the foregoing steps, the semiconductor device 10 shown in FIG. 1 is completed.

As described so far, in the manufacturing method, since a material of the withstand voltage layer 34 (AlGaN) is different from a material of the first drift layer 38 (GaN), the etching rate changes at the interface between these materials. Therefore, when the opening 62 is formed, it is possible to determine based on the etching rate that the opening 62 has reached the first drift layer 38. Alternatively, when the etching apparatus has a function of detecting an Al ratio, it is possible to determine that the opening 62 has reached the first drift layer 38 when Al is detected once and then no longer detected thereafter. Thus, the bottom surface of the opening 62 is almost leveled with the upper surface of the first drift layer 38. Therefore, variation in a depth of the opening 62 (that is a depth of the second drift layer 36) is restrained. Because of this, variation in characteristics of the semiconductor device 10 is restrained when the semiconductor device 10 is mass-produced.

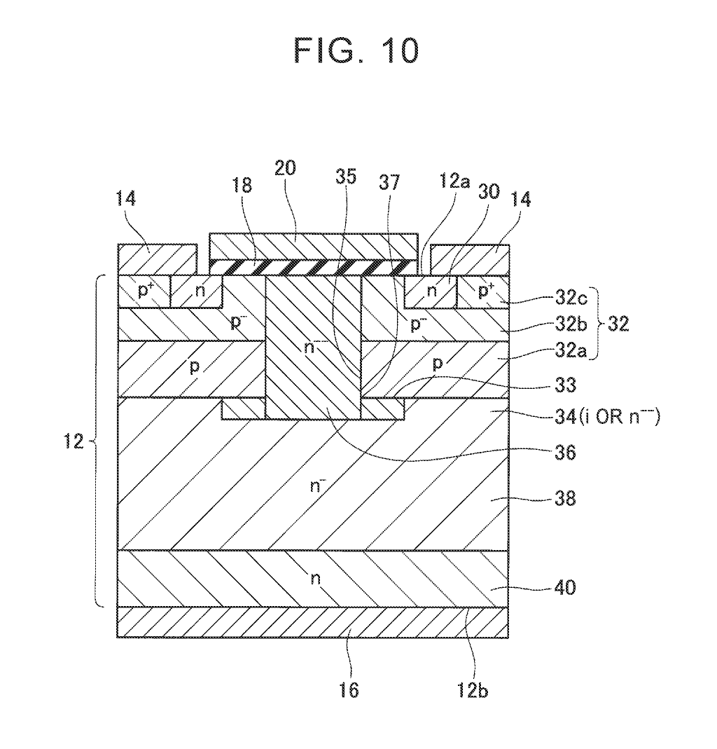

In the foregoing embodiment, the withstand voltage layer 34 is provided underneath the entire body layer 32. However, the withstand voltage layer 34 may be provided only in an area underneath the body layer 32 where an electric field concentration becomes a problem. For example, as shown in FIG. 10, the withstand voltage layer 34 may be provided underneath the corner portion 37 (that is an end portion of the lower surface of the body layer 32 on the second drift layer 36 side), and the first drift layer 38 may be in contact with the lower surface of the body layer 32 in the remaining range.

Further, in the foregoing embodiment, the first drift layer 38 is made from GaN, and the withstand voltage layer 34 is formed from AlGaN. However, as long as the relation that the bandgap of the withstand voltage layer 34 is larger than the bandgap of the first drift layer 38 is satisfied, any material may be used to make the withstand voltage layer 34 and the first drift layer 38. The first drift layer 38 may be made from, for example, GaN, AlGaN, or Ga₂O₃. The withstand voltage layer 34 may be made from, for example, AlGaN or AlN. Both the first drift layer 38 and the withstand voltage layer 34 may be made from AlGaN. In this case, an Al ratio in the withstand voltage layer 34 is set to be higher than an Al ratio in the first drift layer 38, and then the bandgap of the withstand voltage layer 34 becomes higher than the bandgap of the first drift layer 38.

Furthermore, in the foregoing embodiment, the drain layer 40 is described as a monolayer. However, the drain layer 40 may include a buffer layer that is in contact with the first drift layer 38, and a high concentration layer disposed between the buffer layer and the drain electrode 16. In this case, an n-type impurity concentration of the buffer layer may be set to be higher than the n-type impurity concentration of the first drift layer 38, and an n-type impurity concentration of the high concentration layer may be set to be higher than the n-type impurity concentration of the buffer layer.

The technical elements disclosed in this specification are listed below. Each of the technical elements is useful independently.

In the semiconductor device disclosed as an example in this specification, the withstand voltage layer may be in contact with the end portion of the lower surface of the body layer on the second drift layer side.

In the end portion of the lower surface of the body layer on the second drift layer side, an electric field tends to concentrate. Therefore, by providing the withstand voltage layer in this position, withstand voltage of the semiconductor device is improved further.

In the semiconductor device disclosed as an example in this specification, the first drift layer may be made from GaN, and the withstand voltage layer may be made from AlGaN or AlN.

In the semiconductor device as an example disclosed in this specification, the n-type impurity concentration of the withstand voltage layer may be lower than the n-type impurity concentration of the first drift layer.

With this configuration, an electric field inside the withstand voltage layer is restrained. Thus, withstand voltage of the semiconductor device is improved further.

In the semiconductor device disclosed as an example in this specification, the n-type impurity concentration of the second drift layer may be lower than the n-type impurity concentration of the first drift layer.

With this configuration, a depletion layer spreads in the second drift layer easily, thereby restraining application of an electric field to the gate insulating film.

In the semiconductor device disclosed as an example in this specification, the body layer may include a first body layer and a second body layer. The first body layer may be disposed on top of the withstand voltage layer. The second body layer may have a p-type impurity concentration lower than that of the first body layer, disposed on top of the first body layer, and face the gate electrode between the second drift layer and the source layer.

With this configuration, since the p-type impurity concentration of the first body layer is high, the depletion layer tends to spread upwardly from the interface between the body layer and the withstand voltage layer. Thus, it is possible to prevent a punchthrough.

In the semiconductor device disclosed as an example in this specification, the n-type drain layer may be further included. The drain layer is in contact with a bottom of the first drift layer, and has the n-type impurity concentration higher than that of the first drift layer.

In addition, this specification proposes a new manufacturing method for a semiconductor device. The manufacturing method includes first to sixth steps. In the first step, an i-type or an n-type withstand voltage layer made from AlGaN is grown on top of an n-type first drift layer made from GaN. In the second step, a p-type body layer is formed on top of the withstand voltage layer. In the third step, an opening is formed by the etching. The opening penetrates the body layer and the withstand voltage layer and reaches the first drift layer. In the fourth step, an n-type second drift layer is formed inside the opening. In the fifth step, an n-type source layer is formed. The source layer is separated from the first drift layer, the second drift layer, and the withstand voltage layer by the body layer. In the sixth step, a gate electrode is formed. The gate electrode faces the body layer through a gate insulating film, the body layer being positioned between the source layer and the second drift layer.

In this manufacturing method, the opening that penetrates the body layer and the withstand voltage layer and reaches the first drift layer is formed by etching the body layer and the withstand voltage layer. In this case, once the opening penetrates the withstand voltage layer, an object to be etched changes from the withstand voltage layer to the first drift layer. Since the materials of the withstand voltage layer (that is AlGaN) and the first drift layer (that is GaN) are different, an etching rate changes at this point. By detecting the change in the etching rate, it is possible to determine that the opening has reached the first drift layer. Alternatively, when an etching apparatus has a function of detecting an Al ratio, it is determined that the opening has reached the first drift layer when Al is detected once and then no longer detected thereafter. Hence, by stopping the etching when the opening reaches the first drift layer, then excessive etching of the first drift layer is prevented. Therefore, with this manufacturing method, it is possible to restrain variation in characteristics of the semiconductor device when the semiconductor device is mass-produced.

What is claimed is:

1. A semiconductor device comprising:
a first drift layer containing an n-type impurity;
a withstand voltage layer that is disposed on top of the first drift layer and contains an i-type or the n-type impurity;
a body layer that is disposed on top of the withstand voltage layer and contains a p-type impurity;
a second drift layer that is disposed on top of the first drift layer, is in contact with a side surface of the withstand voltage layer and a side surface of the body layer, and contains the n-type impurity;
a source layer that is disposed on top of the body layer, is separated from the first drift layer, the second drift layer, and the withstand voltage layer by the body layer, and contains the n-type impurity; and
a gate electrode that faces the body layer through a gate insulating film, the body layer being positioned between the second drift layer and the source layer, wherein
the withstand voltage layer is made from a material having a bandgap larger than that of the first drift layer.

2. The semiconductor device according to claim 1, wherein the withstand voltage layer is in contact with an end portion of a lower surface of the body layer on a side of the second drift layer.

3. The semiconductor device according to claim 1, wherein:
the first drift layer is made from GaN; and
the withstand voltage layer is made from AlGaN or AlN.

4. The semiconductor device according to claim 1, wherein a concentration of the n-type impurity in the withstand voltage layer is lower than a concentration of the n-type impurity in the first drift layer.

5. The semiconductor device according to claim 1, wherein a concentration of the n-type impurity in the second drift layer is lower than a concentration of the n-type impurity in the first drift layer.

6. The semiconductor device according to claim 1, wherein the body layer includes:
a first body layer disposed on top of the withstand voltage layer; and
a second body layer that contains the p-type impurity less concentrated than that of the first body layer, is disposed on top of the first body layer, and faces the gate electrode between the second drift layer and the source layer.

7. The semiconductor device according to claim 1, further comprising a drain layer that is in contact with a bottom of the first drift layer, and contains the n-type impurity more concentrated than that of the first drift layer.

8. A manufacturing method for a semiconductor device, comprising:
allowing a withstand voltage layer to grow on top of a first drift layer, the withstand voltage layer being made from AlGaN and containing an i-type or an n-type impurity, the first drift layer being made from GaN and containing the n-type impurity;
forming a body layer on top of the withstand voltage layer, the body layer containing a p-type impurity;
forming an opening by etching, the opening penetrating the body layer and the withstand voltage layer and reaching the first drift layer;
forming a second drift layer inside the opening, the second drift layer containing the n-type impurity;
forming a source layer that contains the n-type impurity and is separated from the first drift layer, the second drift layer, and the withstand voltage layer by the body layer; and
forming a gate electrode that faces the body layer through a gate insulating film, the body layer being positioned between the source layer and the second drift layer.
